(19) United States
(12) Patent Application Publication
(10) Pub. No.: US 2024/0161813 A1
(43) Pub. Date: May 16, 2024

(54) SENSE AMPLIFIER AND NONVOLATILE MEMORY DEVICE

(71) Applicant: ROHM CO., LTD., Kyoto (JP)

(72) Inventor: Seiichi YAMAMOTO, Kyoto (JP)

(21) Appl. No.: 18/502,661

(22) Filed: Nov. 6, 2023

(30) Foreign Application Priority Data
Nov. 10, 2022 (JP) 2022-180407

(51) Int. Cl. G11C 11/4091; G11C 11/4093; G11C 11/4096

(52) U.S. Cl. CPC G11C 11/4091; G11C 11/4093; G11C 11/4096

(57) ABSTRACT

A sense amplifier includes: a first current mirror including a diode-connected first input side transistor and a first output side transistor; a bit line connected between the first input side transistor and a memory cell; a reference line connected between the first output side transistor and a reference current generation circuit; an output stage connected to the reference line and configured to output a read signal based on a voltage of the reference line; and a first switch connected between the bit line and the reference line.

### CROSS-REFERENCE TO RELATED APPLICATION

This application is based upon and claims the benefit of priority from Japanese Patent Application No. 2022-180407, filed on Nov. 10, 2022, the entire contents of which are incorporated herein by reference.

### TECHNICAL FIELD

The present disclosure relates to a sense amplifier and a nonvolatile memory device.

### BACKGROUND

In the related art, a nonvolatile memory device including a memory cell is known. The memory cell is constituted by a transistor. A certain memory cell includes a floating gate and performs injection and extraction of electrons with respect to the floating gate to perform erasing and writing (program).

### BRIEF DESCRIPTION OF DRAWINGS

The accompanying drawings, which are incorporated in and constitute a part of the specification, illustrate embodiments of the present disclosure.

FIG. 1 is a diagram showing a configuration of a nonvolatile memory device according to an embodiment of the present disclosure.

FIG. 2 is a timing chart illustrating an example of a read operation performed by a sense amplifier according to an embodiment of the present disclosure.

FIG. 3 is a diagram showing a configuration of a nonvolatile memory device according to a comparative example.

FIG. 4 is a timing chart showing an example of a read operation performed by a sense amplifier according to a comparative example.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Exemplary embodiments of the present disclosure will be described below with reference to the drawings.

### 1. Comparative Example

Before describing the embodiment of the present disclosure, a comparative example for comparison will be described. By describing the comparative example, issues will become clearer.

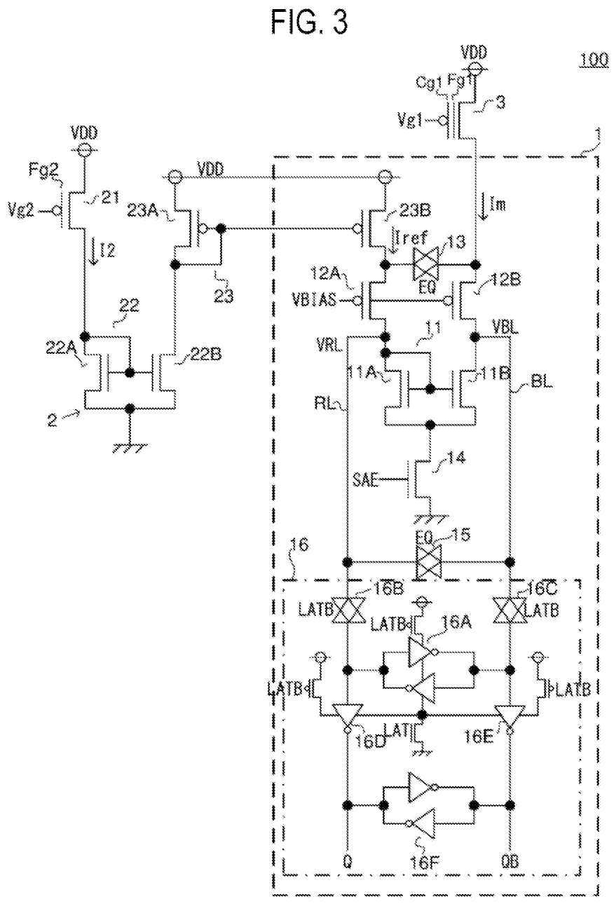

FIG. 3 is a diagram showing a configuration of a nonvolatile memory device 100 according to a comparative example. FIG. 3 shows a partial circuit configuration of the nonvolatile memory device 100. As shown in FIG. 3, the nonvolatile memory device 100 includes a sense amplifier 1, a reference current generation circuit 2, and a memory cell 3.

The memory cell 3 is constituted by a PMOS transistor (P-channel MOSFET (metal-oxide-semiconductor field-effect transistor)) and is an element configured to store data. The memory cell 3 includes a control gate Cg1 and a floating gate Fg1. By applying a high voltage to the control gate Cg1, electrons are injected into and extracted from the floating gate Fg1 via an oxide film. The threshold voltage Vt of the memory cell 3 is changed depending on a state of electrons in the floating gate Fg1. By applying a gate voltage Vg1 set to a median value among the varying threshold voltages Vt to the control gate Cg1 of the memory cell 3, the memory cell 3 comes into an on-state (a state in which a current flows) or an off-state (a state in which no current flows). In this way, as a charge state of the floating gate Fg1, the memory cell 3 may be set to a program state or an erase state, and data may be read by the current flowing through the memory cell 3.

Although only one memory cell 3 is shown in FIG. 3 for the sake of convenience, a large number of memory cells 3 are actually connected to a PMOS transistor 12B, and one of the memory cells 3 may be selected.

The reference current generation circuit 2 is a circuit configured to generate a reference current Iref, and includes a pseudo memory cell 21 and current mirrors 22 and 23.

The pseudo memory cell 21 is constituted by a PMOS transistor and includes a floating gate Fg2 (not including a control gate). The pseudo memory cell 21 is manufactured by the same process as the memory cell 3, and has the same transistor size as the memory cell 3. A gate voltage Vg2 is applied to the floating gate Fg2.

The current mirror 22 includes an input side transistor 22A and an output side transistor 22B. The input side transistor 22A and the output side transistor 22B are constituted by NMOS transistors (N channel MOSFETs). A drain and a gate of the input side transistor 22A are short-circuited. Sources of the input side transistor 22A and the output side transistor 22B, respectively, are connected to a ground end (ground potential application end). The gates of the input side transistor 22A and the output side transistor 22B are connected to each other. In this way, the input side transistor 22A is diode-connected.

The current mirror 23 includes an input side transistor 23A and an output side transistor 23B. The input side transistor 23A and the output side transistor 23B are constituted by PMOS transistors. A drain and a gate of the input side transistor 23A are short-circuited. Sources of the input side transistor 23A and the output side transistor 23B, respectively, are connected to an application terminal of a power supply voltage VDD. The gates of the input side transistor 23A and the output side transistor 23B are connected to each other. In this way, the input side transistor 23A is diode-connected.

A source of the pseudo memory cell 21 is connected to the application terminal of the power supply voltage VDD. A drain of the pseudo memory cell 21 is connected to the drain of the input side transistor 22A. A drain of the output side transistor 22B is connected to the drain of the input side transistor 23A. A current I2 flowing through the pseudo memory cell 21 by applying the gate voltage Vg2 to the floating gate Fg2 is mirrored in order by the current mirrors 22 and 23, and is used as a reference current Iref flowing through the output side transistor 23B. Since the pseudo memory cell 21 is highly likely to be paired with the memory cell 3, it is suitable for generating a reference current Iref for comparison with a memory current Im flowing through the memory cell 3.

The sense amplifier 1 is a circuit configured to read data from the memory cell 3 based on the comparison between the memory current Im flowing through the memory cell 3 and the reference current Tref. The sense amplifier 1 includes a current mirror 11, PMOS transistors 12A and 12B, a switch 13, an NMOS switch 14, a switch 15, and an output stage 16. The sense amplifier 1 further includes the output side transistor 23B of the current mirror 23 described above.

The current mirror 11 includes an input side transistor 11A and an output side transistor 11B. The input side transistor 11A and the output side transistor 11B are constituted by NMOS transistors. A drain and a gate of the input side transistor 11A are short-circuited. Sources of the input side transistor 11A and the output side transistor 11B, respectively, are connected to a drain of the NMOS switch 14. The NMOS switch 14 is constituted by an NMOS transistor. A source of the NMOS switch 14 is connected to the ground end. The gates of the input side transistor 11A and the output side transistor 11B are connected to each other. In this way, the input side transistor 11A is diode-connected. The on/off state of the NMOS switch 14 is controlled by a switch control signal SAE applied to the gate of the NMOS switch 14.

The drain of the input side transistor 11A is connected to a drain of a PMOS transistor 12A for a cascode connection. A source of the PMOS transistor 12A is connected to a drain of the output side transistor 23B.

A drain of the output side transistor 11B is connected to a drain of the PMOS transistor 12B for a cascode connection. A source of the PMOS transistor 12B is connected to a drain of the memory cell 3. A source of the memory cell 3 is connected to the application terminal of the power supply voltage VDD. An equalization switch 13 is connected between the sources of the PMOS transistors 12A and 12B. The switch 13 is controlled to be turned on or off by an equalization signal EQ. A bias voltage VBIAS is applied to each of the gates of the PMOS transistors 12A and 12B.

A reference line RL is connected between the input side transistor 11A and the PMOS transistor 12A. A bit line BL is connected between the output side transistor 11B and the PMOS transistor 12B. An equalization switch 15 is connected between the reference line RL and the bit line BL. The switch 15 is controlled to be turned on or off by an equalization signal EQ.

The output stage 16 is connected to the reference line RL and the bit line BL. The output stage 16 includes a latch circuit 16A, switches 16B and 16C, inverters 16D and 16E, and a latch circuit 16F.

The latch circuit 16A includes two inverters. An input end of one inverter is connected to an output end of the other inverter at a first end. An output end of one inverter is connected to an input end of the other inverter at a second end. The switch 16B is connected between the reference line RL and the first end of the latch circuit 16A. A switch 16C is connected between the bit line BL and the second end of the latch circuit 16A. The switches 16B and 16C are turned on and off by a latch bar signal LATB. The latch bar signal LATB is a signal obtained by inverting a logic of a latch signal LAT.

Whether or not to apply the ground potential to the latch circuit 16A is switched by the latch signal LAT. Whether or not to apply the power supply voltage to the latch circuit 16A is switched by the latch bar signal LATB.

A first end of the latch circuit 16A is connected to an input end of the inverter 16D. A second end of the latch circuit 16A is connected to an input end of an inverter 16E. Whether or not to apply the ground potential to the inverters 16D and 16E is switched by the latch signal LAT. Whether or not to apply the power supply voltage to the inverters 16D and 16E is switched by the latch bar signal LATB.

Like the latch circuit 16A, the latch circuit 16F is constituted by two inverters and includes a first end and a second end. An output end of the inverter 16D is connected to a first end of latch circuit 16F. An output end of the inverter 16E is connected to a second end of the latch circuit 16F. A read signal Q is outputted from the output end of the inverter 16D. A read signal QB (Q bar) is outputted from the output end of the inverter 16E.

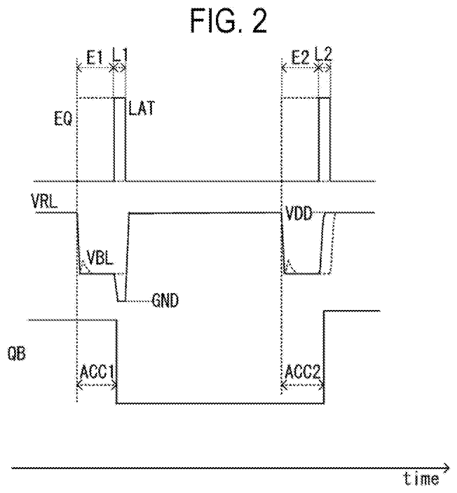

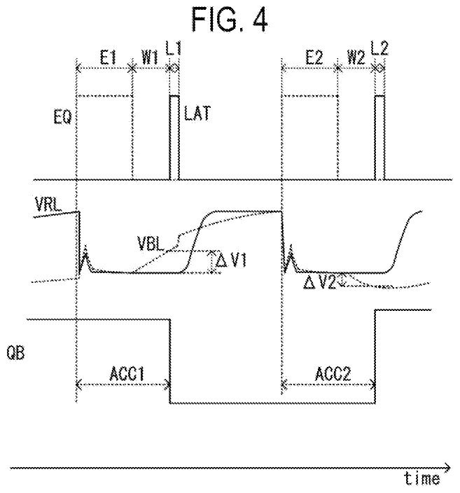

A read operation performed by the sense amplifier 1 according to such a comparative example will be described with reference to the timing chart of FIG. 4. In FIG. 4, a horizontal axis is a time axis. Waveform examples of the equalization signal EQ (broken line), the latch signal LAT (solid line), a voltage VRL of the reference line RL (solid line), a voltage VBL of the bit line BL (broken line), and the read signal QB are indicated sequentially from the top. The same applies to FIG. 2, which will be described later.

First, the equalization signal EQ rises from a low level to a high level, and equalization is started (start of an equalization period E1). As a result, the switches 13 and 15 are switched from an off-state to an on-state. The equalization enables the voltage VRL to match the voltage VBL. At this time, the switch control signal SAE is switched from a low level to a high level. Therefore, the NMOS switch 14 is switched from an off-state to an on-state. As a result, the reference line RL is discharged via the diode-connected input side transistor 11A and the NMOS switch 14. On the other hand, the bit line BL is discharged via the switch 15, the diode-connected input side transistor 11A, and the NMOS switch 14, and via the output side transistor 11B and the NMOS switch 14.

By the end of the equalization period E1 in which the equalization signal EQ is switched from a high level to a low level, the voltage VRL and the voltage VBL almost match. Then, when the equalization signal EQ is switched from the high level to the low level, the switches 13 and 15 are turned off, and a waiting time W1 is started. Although the voltage VRL is maintained during the waiting time W1, behavior of the voltage VBL is changed depending on the memory current Im generated by the memory cell 3. In this case, the memory current Im generated by the selected memory cell 3 flows, Im>Iref, and the voltage VBL rises. The application of the gate voltage Vg1 to the memory cell 3 is started before and after the equalization period E1 is started. The memory current Im flows at the same time as the application of the gate voltage Vg1 starts.

When the predetermined waiting time W1 has elapsed, the latch signal LAT is switched from the low level to the high level, and a latch period L1 is started. At this time, the latch bar signal LATB is switched from the high level to the low level. As a result, the ground potential and the power supply voltage are applied to the latch circuit 16A and the inverters 16D and 16E, such that the latch circuit 16A and the inverters 16D and 16E become valid.

In the latch period L1, an amplitude AV1 of the voltage VBL and the voltage VRL is ensured. Therefore, the read signal QB and the read signal Q are latched by the latch circuit 16A such that the read signal QB is determined to be at a low level and the read signal Q is determined to be at a high level. When the latch signal LAT is switched from the high level to the low level, the latch period L1 comes to an end, and the latch circuit 16A and the inverters 16D and 16E become invalid. Thereafter, the read signals Q and QB are held by the latch circuit 16F.

When the latch period L1 comes to an end, the NMOS switch 14 is switched to an off-state by the switch control signal SAE, and the voltages VRL and VBL rise. The voltage VBL rises because of the state in which the memory current Im flows through the memory cell 3.

Thereafter, the equalization signal EQ rises from the low level to the high level, and equalization is started (start of an equalization period E2). In the equalization period E2, the voltage VRL and the voltage VBL match. Then, when the equalization signal EQ is switched from the high level to the low level, a waiting time W2 is started. In this case, the memory current Im generated by the selected memory cell 3 does not flow, Iref>Im, and the voltage BL decreases. At this time, the voltage VRL is maintained.

When the predetermined waiting time W2 has elapsed, the latch signal LAT is switched from a low level to a high level, and a latch period L2 is started. In the latch period L2, an amplitude AV2 of the voltage VBL and the voltage VRL is secured. Therefore, the read signal QB and the read signal Q are latched by the latch circuit 16A such that the read signal QB is determined to be at a high level and the read signal Q is determined to be at a low level. When the latch signal LAT is switched from the high level to the low level, the latch period L2 comes to an end. Thereafter, the read signals Q and QB are held by the latch circuit 16F. At this time, the voltage VRL increases, but the voltage VBL does not easily increase. Since the memory current Im does not flow through the memory cell 3, it is difficult for the voltage VBL to rise.

In this way, the data of the memory cell 3 is read by the sense amplifier 1 according to the comparative example. However, the sense amplifier 1 according to the comparative example has room for improvement in the reading time for the following reasons. The time from the start of equalization to the confirmation of read data is an access time. It is desirable to shorten the access time. In the example of FIG. 4, the access times includes an access time ACC1 after the start of the equalization period E1 and an access time ACC2 after the start of the equalization period E2.

In the comparative example, the bit line BL is discharged via the switch 15 during the equalization period. Therefore, an impedance of a discharge path becomes large. In addition, since parasitic capacitance on the side of the memory cell 3 is much larger than that on the side of the reference current Iref (output side transistor 23B), it may take a long time for the voltage VBL to decrease and converge. Therefore, it is necessary to lengthen the equalization period.

Further, since the parasitic capacitance on the side of the memory cell 3 is very large, a change rate of the voltage VBL is small, which makes it difficult to increase the amplitudes AV1 and AV2 due to the rise or fall of the voltage VBL. Furthermore, it is necessary to provide a waiting time for waiting until the amplitudes AV1 and AV2 are secured. For these reasons, in the comparative example, there is room for improvement in access time.

### 2. Embodiment of the Present Disclosure

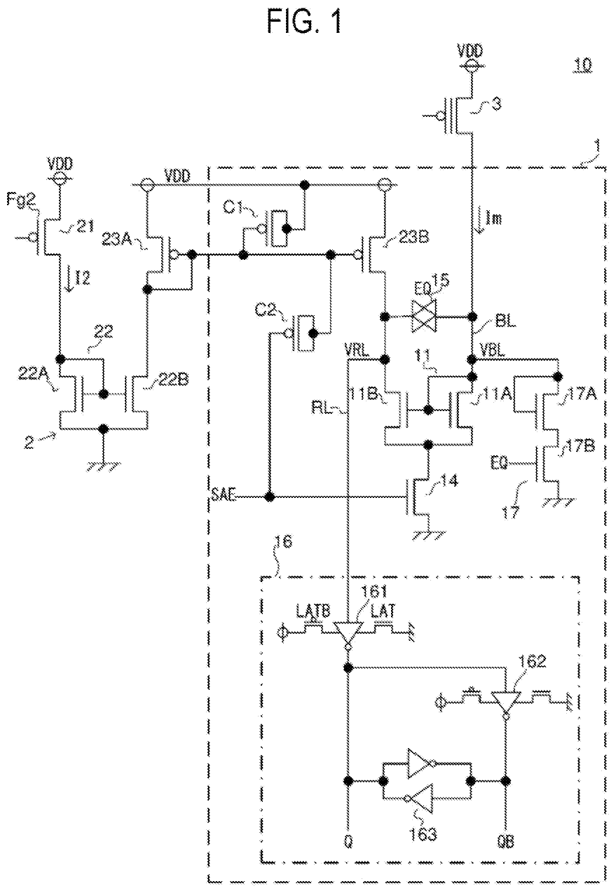

FIG. 1 is a diagram showing a configuration of a nonvolatile memory device 10 according to an exemplary embodiment of the present disclosure. The nonvolatile memory device 10 includes a sense amplifier 1, a reference current generation circuit 2, and a memory cell 3.

Since the reference current generation circuit 2 and the memory cell 3 are the same as those in the comparative example, differences in the configuration of the sense amplifier 1 from the comparative example will be mainly described herein.

In the sense amplifier 1 according to the present embodiment, unlike the comparative example, the diode-connected input side transistor 11A is on the side of the memory cell 3, and the output side transistor 11B is on the side of the reference current Iref. Further, in the present embodiment, the PMOS transistors 12A and 12B for a cascode connection are not provided. The drain of the input side transistor 11A is connected to the drain of the memory cell 3. A bit line BL is connected between the input side transistor 11A and the memory cell 3.

In the present embodiment, the drain of the output side transistor 11B is connected to the drain of the output side transistor 23B. A reference line RL is connected between the output side transistor 11B and the output side transistor 23B. An equalization switch 15 is connected between the reference line RL and the bit line BL. The switch 15 is controlled to be turned on or off by an equalization signal EQ.

The output stage 16 is connected to the reference line RL. The output stage 16 includes inverters 161 and 162 and a latch circuit 163. An input end of the inverter 161 is connected to the reference line RL. An input end of the inverter 162 is connected to an output end of the inverter 161.

In the inverters 161 and 162, whether or not to apply a ground potential to the inverters 161 and 162 is switched by the latch signal LAT, and whether or not to apply a power supply voltage to the inverters 161 and 162 is switched by the latch bar signal LATB.

The latch circuit 163 is constituted by two inverters just like the latch circuit 16A according to the comparative example described above, and includes a first end and a second end. The output end of the inverter 161 is connected to the first end of the latch circuit 163. The output end of the inverter 162 is connected to the second end of the latch circuit 163. A read signal Q is outputted from the output end of the inverter 161. A read signal QB is outputted from the output end of the inverter 162.

Further, the sense amplifier 1 according to the present embodiment includes a discharge assist circuit 17. The discharge assist circuit 17 includes a diode-connected NMOS transistor 17A and an NMOS switch 17B. A drain of the NMOS transistor 17A is connected to the bit line BL. A source of the NMOS transistor 17A is connected to a drain of the NMOS switch 17B. A source of the NMOS switch 17B is connected to the ground end. The NMOS switch 17B is turned on and off by the equalization signal EQ.

Further, the sense amplifier 1 according to the present embodiment includes MOS capacitors C1 and C2. The MOS capacitor C1 is connected between each of the gates of the input side transistor 23A and the output side transistor 23B and the application terminal of the power supply voltage VDD. The MOS capacitor C1 is provided to suppress a decrease in the voltage VRSA at each of the gates of the input side transistor 23A and the output side transistor 23B and a change in the reference current Tref when the switch control signal SAE is switched from a low level to a high level and the NMOS switch 14 is switched to an on-state.

The MOS capacitor C2 is connected between the application end of the switch control signal SAE and each of the gates of the input side transistor 23A and the output side transistor 23B. The MOS capacitor C2 is provided to cancel a decrease in the voltage VRSA by the switch control signal SAE when the switch control signal SAE rises to a high level and the NMOS switch 14 is switched to an on-state.

The read operation performed by the sense amplifier 1 according to the present embodiment will be described with reference to the timing chart of FIG. 2.

First, the equalization signal EQ rises from a low level to a high level, and equalization is started (start of an equalization period E1). Thus, the switch 15 is switched from an off-state to an on-state. The equalization enables the voltage VRL to match the voltage VBL. At this time, the switch control signal SAE is switched from a low level to a high level. Therefore, the NMOS switch 14 is switched from an off-state to an on-state. As a result, the reference line RL is discharged via the switch 15, the diode-connected input side transistor 11A, and the NMOS switch 14. On the other hand, the bit line BL is discharged via the diode-connected input side transistor 11A and the NMOS switch 14.

Further, when the equalization signal EQ rises from a low level to a high level, the NMOS switch 17B is switched to an on-state, and the bit line BL is forcibly discharged by the discharge assist circuit 17.

By the end of the equalization period E1 in which the equalization signal EQ is switched from a high level to a low level, the voltage VRL and the voltage VBL match. Then, when the equalization signal EQ is switched from the high level to the low level, the switch 15 and the NMOS switch 17B are switched to an off-state. At this time, the latch signal LAT is switched from a low level to a high level, and the latch period L1 is started. That is, in the present embodiment, the waiting time as in the comparative example is not provided.

When the latch period L1 is started, the ground potential and the power supply voltage are applied to the inverters 161 and 162 such that the inverters 161 and 162 become valid. When the latch period L1 is started, the voltage VBL of the bit line BL is maintained, but behavior of the voltage VRL of the reference line RL is changed depending on a magnitude relationship between the memory current Im generated by the memory cell 3 and the reference current Tref.

In this case, the memory current Im flows, Im>Iref, and the voltage VRL decreases. At this time, the voltage VRL immediately falls to the ground potential. Therefore, during the latch period L1, the read signal Q is determined to be at a high level and the read signal QB is determined to be at a low level. When the latch signal LAT is switched to a low level and the latch period L1 comes to an end, the inverters 161 and 162 become invalid, and the read signals Q and QB held by the latch circuit 163 are outputted.

Thereafter, the equalization in the equalization period E2 is similarly finished, and the latch period L2 is started. In this case, the memory current Im does not flow, Iref>Im, and the voltage VRL increases. At this time, the voltage VRL immediately rises to the power supply voltage VDD. Therefore, in the latch period L2, the read signal Q is determined to be at a low level and the read signal QB is determined to be at a high level. When the latch period L2 comes to an end, the inverters 161 and 162 become invalid, and the read signals Q and QB held by the latch circuit 163 are outputted.

As described above, in the present embodiment, by placing the input side transistor 11A on the side of the memory cell 3, regardless of the large parasitic capacitance on the side of the memory cell 3, an impedance of a path for discharging the bit line BL during equalization may be lowered, and a time for the voltage VBL to converge may be shortened. Further, by forcibly discharging the bit line BL with the discharge assist circuit 17, the time for the voltage VBL to converge may be further shortened. Therefore, it is possible to shorten the equalization period. Since the parasitic capacitance on the side of the reference current Tref is small, even in a case where the reference line RL is discharged via the switch 15 during the equalization, there is little influence on a convergence time of the voltage VRL.

Furthermore, since the parasitic capacitance on the side of the reference current Tref is small, the voltage VRL is immediately changed to the ground potential or the power supply voltage VDD after the equalization. Therefore, even without providing a waiting time after equalization, the voltage VRL is changed within the latch period, and the read signals Q and QB are determined.

As described above, in the present embodiment, the equalization period is shortened and the waiting time is not required. Therefore, it is possible to shorten the access time (ACC1 and ACC2 in FIG. 2). Further, since the voltage VRL is changed to the ground potential or the power supply voltage VDD during the latch period, the voltage VRL may be received by the inverters 161 and 162 in the output stage 16. This makes it possible to simplify the configuration of the output stage 16. For example, two inverters may be provided between the inverter 161 and the first end of the latch circuit 163.

Further, even in a case where the voltage VRL changes in an opposite direction from an original direction due to switching noise at the start of the latch period, it immediately changes in a correct direction. Since the inverters 161 and 162 are valid during the latch period, correct read signals Q and QB are determined within the latch period.

In the comparative example (FIG. 3), since the Vgs (gate-source voltage) of the input side transistor 22A is fixed, a drain-source voltage Vds of the pseudo memory cell 21 is fixed. In the current mirror 11, Vgs of the input side transistor 11A is fixed, but Vds of the output side transistor 11B is variable, and Vds of the memory cell 3 is variable.

On the other hand, in the present embodiment (FIG. 1), Vgs of the input side transistor 22A is fixed, and therefore Vds of the pseudo memory cell 21 is fixed. However, Vgs of the input side transistor 11A of the current mirror 11 is fixed. Therefore, Vds of the memory cell 3 is fixed, and quality of electrical pairing between the pseudo memory cell 21 and the memory cell 3 is improved.

### 3. Others

Various technical features disclosed in the present disclosure are not limited to the above-described embodiments but may be modified in various forms without departing from the spirit of its technical creation. That is, the above-described embodiments should be considered to be exemplary in all respects and not limitative. It should be understood that the technical scope of the present disclosure is not limited to the above-described embodiments, and encompasses all changes that fall within meaning and range equivalent to the claims.

### 4. Supplementary Note

As described above, for example, the sense amplifier (1) according to one aspect of the present disclosure includes: a first current mirror (11) including a diode-connected first input side transistor (11A) and a first output side transistor (11B); a bit line (BL) connected between the first input side transistor and a memory cell (3); a reference line (RL) connected between the first output side transistor and a reference current generation circuit (2); an output stage (16) connected to the reference line and configured to output a read signal based on a voltage (VRL) of the reference line; and a first switch (15) connected between the bit line and the reference line (first configuration).

Further, the sense amplifier of the first configuration further includes: a discharge assist circuit (17) connected to the bit line (BL), wherein the discharge assist circuit includes a diode-connected transistor (17A) and a second switch (17B) controlled to be turned on and off in synchronization with the first switch (second configuration).

Further, in the sense amplifier of the first or second configuration, the output stage (16) includes an inverter (161) configured to receive the voltage (VRL) of the reference line and a latch circuit (163) connected to an output end of the inverter (third configuration).

Further, the sense amplifier of any one of the first to third configurations further includes: a PMOS transistor (23B) included in the reference current generation circuit (2) and configured to allow a reference current (Tref) to flow therethrough; and an NMOS switch (14) connected between the first current mirror (11) and a ground end (fourth configuration).

Further, the sense amplifier of the fourth configuration further includes: a first capacitor (C1) connected between a gate of the PMOS transistor (23B) and an application terminal of a power supply voltage (VDD) (fifth configuration).

Further, the sense amplifier of the fourth or fifth configuration further includes: a second capacitor (C2) connected between the gate of the PMOS transistor (23B) and a gate of the NMOS switch (14) (sixth configuration).

A nonvolatile memory device (10) according to an aspect of the present disclosure includes: the sense amplifier (1) of any one of the first to sixth configurations; a reference current generation circuit (2); and a memory cell (3) (seventh configuration).

Further, in the nonvolatile memory device of the seventh configuration, the reference current generation circuit (2) includes a pseudo memory cell (21) manufactured by a process which is the same as a process by which the memory cell is manufactured (3) (eighth configuration).

Further, in the nonvolatile memory device of the eighth configuration, the reference current generation circuit (2) includes a second current mirror (22) including a second input side transistor (22A) connected to the pseudo memory cell (21) (ninth configuration).

The present disclosure may be used in memory circuits for various purposes.

According to the present disclosure in some embodiments, it is possible to accelerate a data readout

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A sense amplifier, comprising:
a first current mirror including a diode-connected first input side transistor and a first output side transistor;
a bit line connected between the diode-connected first input side transistor and a memory cell;
a reference line connected between the first output side transistor and a reference current generation circuit;
an output stage connected to the reference line and configured to output a read signal based on a voltage of the reference line; and
a first switch connected between the bit line and the reference line.

2. The sense amplifier of claim 1, further comprising:
a discharge assist circuit connected to the bit line,
wherein the discharge assist circuit includes a diode-connected transistor and a second switch controlled to be turned on and off in synchronization with the first switch.

3. The sense amplifier of claim 1, wherein the output stage includes an inverter configured to receive the voltage of the reference line and a latch circuit connected to an output end of the inverter.

4. The sense amplifier of claim 1, further comprising:
a PMOS transistor included in the reference current generation circuit and configured to allow a reference current to flow therethrough; and
an NMOS switch connected between the first current mirror and a ground end.

5. The sense amplifier of claim 4, further comprising:
a first capacitor connected between a gate of the PMOS transistor and an application end of a power supply voltage.

6. The sense amplifier of claim 4, further comprising:
a second capacitor connected between a gate of the PMOS transistor and a gate of the NMOS switch.

7. A nonvolatile memory device, comprising:
the sense amplifier of claim 1;
a reference current generation circuit; and
a memory cell.

8. The nonvolatile memory device of claim 7, wherein the reference current generation circuit includes a pseudo memory cell manufactured by a process which is the same as a process by which the memory cell is manufactured.

9. The nonvolatile memory device of claim 8, wherein the reference current generation circuit includes a second current mirror including a second input side transistor connected to the pseudo memory cell.
